(19) United States
(12) Patent Application Publication
(10) Pub. No.: US 2009/0290724 A1
(43) Pub. Date: Nov. 26, 2009

(54) LOUDSPEAKER SYSTEM AND LOUDSPEAKER HAVING A TWEETER ARRAY

(76) Inventors: David Magda Eddy Corynen, Dendermonde (BE); Okke Ouweltjes, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 12/307,945

(22) PCT Filed: Jul. 9, 2007
(86) PCT No.: PCT/IB07/52681

§ 371 Date: Jan. 8, 2009

(30) Foreign Application Priority Data
Jul. 13, 2006 (EP) 06117098.1

(51) Int. Cl. H03G 5/00

(52) U.S. Cl. 381/99

(57) ABSTRACT

A loudspeaker system includes at least two stand-alone loudspeaker devices (1L, 1R) each comprising a frame (3) provided with a vertically oriented array (5) of first loudspeakers (7) for reproducing sound in a higher frequency range. The system further includes a second loudspeaker (13) for reproducing sound in a lower frequency range, wherein the frequency ranges have a crossover frequency f_{c} and 750 Hz<f_{c}<3000 Hz. The first loudspeakers each have a first radiation surface (9) in each array a central area (9a) of each first radiation surface being situated at a distance d from the central area of neighboring first radiation surface, wherein λ/_{fe}<d<1 m, wherein λ/_{fe} is the wavelength of the reproduced sound at the crossover frequency. The system is able of reproduce sound of high fidelity qualification.

### FIELD OF THE INVENTION

The invention relates to a system including at least two stand-alone loudspeaker devices, each comprising a frame provided with an array of first loudspeakers for reproducing sound in a higher frequency range, and a second loudspeaker for reproducing sound in a lower frequency range.

### BACKGROUND OF THE INVENTION

It is known in the field that the ideal loudspeaker can only be approximated by a very small pulsating point source generating the full audible frequency spectrum from 20 Hz to 20 kHz without distortion or compression. A single full-range loudspeaker always suffers from compromising on performance, because of its physical limitations with regard to its non-linear behavior. For this reason arrangements of two loudspeakers, i.e. a first loudspeaker—usually mentioned tweeter—for reproducing sound in a higher frequency range and a second loudspeaker—woofer—for reproducing sound in a lower frequency range are used, to reproduce high quality audio, each loudspeaker working in a specific frequency range. Pursuant to current teaching the loudspeakers in such arrangements are positioned close to each other to come close to the ideal full-range point source. However, such multiple loudspeaker devices are far from ideal and suffer from acoustic phase, level and power irregularities around the crossover frequency, resulting in blur and coloration of the reproduced sound. It is to be noted that the term “crossover frequency” means in this paper the frequency at which the electrically and/or mechanically and/or acoustically reduced sound level of the first loudspeaker and the electrically and/or mechanically and/or acoustically reduced sound level of the second loudspeaker are the same, wherein the sound pressure level of the combination of first and second loudspeaker is substantially balanced, measured at a distance of at least three meters from said combination.

An electrical filter may be used to direct appropriate frequencies to a first speaker or a second speaker of a loudspeaker system and thus to reduce the sound level at other frequencies.

In order to provide a listener with satisfying sound characteristics conventional two-way loudspeaker systems, i.e. systems including a tweeter and a woofer, need to be positioned at ear-height of the listener and must have a relatively large cabinet volume for producing sufficient sound energy in the low frequency range. These requirements causes serious design problems, particularly in case of home applications, because the present consumers do not appreciate big sound boxes at ear-height in their homes.

An alternative for the above-described conventional two-way loudspeaker systems are the so-called line-array systems. Such a system includes a vertically oriented group—the line-array—of closely spaced omni-directional radiating transducers positioned in a straight line, wherein every transducer of the line-array is operated in phase and with an equal amplitude. Due to the acoustic coupling between the transducers a line-array may have a satisfying directivity in the vertical plain. However a good directivity of a line-array is only achievable, as is known, if spatial aliasing between the transducers of the array is avoided. Spatial aliasing occurs for frequencies above the Nyquist frequency f_{nyg}=c/2·Δ, wherein c is the speed of sound and A is the distance between two coherent sound sources placed close to each other relative to the wavelength. Therefore, an efficient line-array, i.e. an array not causing sound cancellation in the high frequency range, requires a huge amount of very small and closely spaced transducers. For this reason, full range line-array systems are difficult to realize and thus expensive.

U.S. Pat. No. 6,834,113B1 discloses a loudspeaker system meant for producing a constant sound-pressure along the whole of its length over large distances. This system comprises a line-source of acoustical radiation comprising three or more low-frequency speaker units, and a separate elongated high-frequency transducer arranged in parallel with the line-source.

### SUMMARY OF THE INVENTION

An object of the invention is to provide a loudspeaker system of the kind described in the preamble, which is able to reproduce sound of an improved quality with respect to the known similar systems.

This object is achieved by the loudspeaker system according to the invention, which includes at least two stand-alone loudspeaker devices, each comprising a frame provided with an array, being a vertically oriented array, considered during use of the system, of first loudspeakers (tweeters) for reproducing sound in a higher frequency range, and a second loudspeaker (woofer) for reproducing sound in a lower frequency range, wherein the frequency ranges have a crossover frequency f_{c} and 750 Hz≦f_{c}≦3000 Hz, which first loudspeakers each have a first radiation surface, in each array a central area of each first radiation surface being situated at a distance d from the central area of a neighboring first radiation surface, wherein λ_{f}_{_{c}}<d<1 m, wherein λ_{f}_{_{c}} is the wavelength of the reproduced sound at the crossover frequency.

The solution according to the invention is based on a two-way speakers configuration with (1) a vertically oriented array of minimal two transducers—the second loudspeakers—to generate sound of frequencies above a crossover frequency, and (2) an enclosed transducer—the second loudspeaker—to generate sound of frequencies below the crossover frequency, wherein the crossover frequency f_{c} is laying between 750 Hz and 300 Hz or substantially equal to one of these values.

The transducers of the array are arranged adjacent each other at a spacing, being the distance d as defined above, between λ_{f}_{_{c}} and 1 m, wherein λ_{f}_{_{c}} is the wavelength at the crossover frequency. In many practical cases the distance d is 0.5 m at the most. In case an array of more than two transducers, generally the transducers are situated in line and may be equally spaced. The application of three or more transducers enables a better power handling.

The array in the inventive configuration, i.e. each of the arrays of first loudspeakers in the system according to the invention, is not a conventional in-line array as described in the foregoing and therefore does not have the features and characteristics, such as closely spaced transducers, of such array. On the contrary, the distance d between adjacent transducers in the arrays of the device of the system according to the invention has a specific value which is larger than the wavelength at crossover frequency. It is experimentally shown that such an arrangement yields a sound reproduction with an enlarged sound image, without any high frequency sound loss. In the experiments no trace of any destructive interference was detected, although this was expected because of the applied relatively large distance between the transducers. In front of the devices a homogeneous vertical wave field was determined in the whole frequency range above the crossover frequency. Although the use of two transducers is sufficient to optimize the wave field, the application of more than two transducers offers more possibilities for optimizing. If the first radiation surface of each first loudspeaker in the arrays has a dimension D, considered in the planes of the first radiation surfaces and perpendicular to the arrays, which is smaller than 50 mm, even a horizontal homogeneous wave field is achievable. The above-described experiments have been done with arrays of three and more than three first loudspeakers, however corresponding results are obtainable with similar arrays of only two first loudspeakers.

Summarizing it can be said that the system according to the invention is able to reproduce sound with an enlarged sound image, has favorable dimensions and has a simple and easy to manufacture configuration. Moreover it has appeared that the system according to the invention has a favorable power handling capacity.

For these reasons the loudspeaker system according to the invention is suitable as a high fidelity device for audio reproduction as well as for TV, video and multi-media sound reinforcement. It offers a solution for current design and performance limitations related to multi-way loudspeaker devices and systems.

A preferred embodiment of the loudspeaker device according to the invention has the parameter 1000 Hz≦f_{c}≦2000 Hz, particularly 1000 Hz≦f_{c}≦1500 Hz.

The lower-frequency range, i.e. the frequency range of the second loudspeaker, extends from a resonance frequency up to the crossover-frequency. The second loudspeaker may have a frequency range from 20 Hz to 10 kHz (typical 50 Hz-5 kHz). The higher frequency range, i.e. the frequency range of the first loudspeakers, extends upwardly from the crossover frequency. The first loudspeakers may have a frequency from 500 Hz to 100 kHz (typical 800 Hz-40 kHz).

A practical embodiment of the loudspeaker device according to the invention has the feature that the first radiation surface of the first loudspeaker has a circular outline and a diameter of 50 mm at the most. The radiation surface is preferable a part of a dome-shaped membrane.

It is preferred to position the second loudspeaker in a level underneath the arrays of first loudspeakers. It may be further preferred to provide the frame of each of the loudspeaker devices with a second loudspeaker for reproducing sound in the lower frequency range.

Embodiments of the loudspeaker system according to the invention are defined in the claims 2 to 10.

The invention further relates to a loudspeaker housing. This housing is in principle based on the same recognition as described in the foregoing paragraphs, particularly the issue of applying an array of first loudspeakers positioned at a well-defined minimal distance to each other.

The loudspeaker housing according to the invention accommodates at least one array, being a vertically oriented array, considered during use of the system, of first loudspeakers for reproducing sound in a higher frequency range, and at least one second loudspeaker for reproducing sound in a lower frequency range, the frequency ranges defining a crossover frequency f_{c}, wherein 750 Hz≦f_{c}≦3000 Hz, which first loudspeakers each have a first radiation surface, in each array a central area of each first radiation surface being situated at a distance d from the central area of a neighboring first radiation surface, wherein λ_{f}_{_{c}}<d<1 m, wherein λ_{f}_{_{c}} is the wavelength of the reproduced sound at the crossover frequency.

This housing has similar results, favorable effects and advantages as the system according to the invention has.

Preferred embodiments of the multiple loudspeaker housing according to the invention and preferred parameters for implementation of this housing have been formulated and mentioned in the claims 12 to 19.

The invention also relates to an audio and/or video apparatus provided with a loudspeaker arrangement formed by the loudspeaker system according to the invention or having the loudspeaker housing according to the invention. The loudspeaker housing may be the housing of the apparatus itself or may be a kind of subhousing. As a result of the applied principle, as explained in the foregoing, the sound quality of the apparatus according to the invention is of a high-end level. The apparatus has the same benefits of the invention as aforesaid. In the context of this paper the video apparatus may be a monitor.

The invention further relates to a stand-alone loudspeaker device, suitable for use in the loudspeaker system according to the invention. This device is defined in claim 21 and has similar benefits as described in the foregoing.

It is to be noted that the German Gebrauchsmuster No. 83 04 832 discloses a loudspeaker arrangement in a TV apparatus. This known arrangement comprises more than one loudspeaker in case of mono sound reproduction and more than two loudspeakers in case of stereo sound reproduction. Particularly, the known arrangement comprises a high-frequency loudspeaker and a low-frequency loudspeaker called subwoofer, and optionally comprises a middle-frequency loudspeaker. The high-frequency loudspeaker—and if present the middle-frequency loudspeaker—radiates from a front wall portion of the TV apparatus, while the subwoofer, which has a frequency range of 40 to 200 or 300 Hz, makes use of air openings to radiate from the rear side or bottom side of the TV apparatus. Thus, the known loudspeaker arrangement applied in the known TV apparatus has hardly any resemblance as to sound aspects with the loudspeaker arrangement applied in the apparatus according to the invention.

It is further to be noted that the German Gebrauchsmuster 16 87 888 discloses a loudspeaker box, which is provided with a high-frequency sound system and low-frequency speaker or a broadband system. The high-frequency sound system is such designed and arranged that it radiates sound with frequencies of about 1.000 Hz or higher not only from a front side but also in other directions, such as backwards. For this reason the applied high-frequency sound system has the specific feature of having a plurality of radiation surfaces. By this feature, among others, the known loudspeaker box is essentially different from the loudspeaker structures according to the invention.

With reference to the Claims it is to be noted that various combinations of features as defined in the Claims are possible and intended within the scope of the invention.

### BRIEF DESCRIPTION OF THE DRAWINGS

The already above-mentioned and other objects, features and advantages of the present invention will become readily apparent from the following detailed exemplary description read in conjunction with the accompanying drawings, in which:

FIG. 1 is a schematic representation of an embodiment of the loudspeaker system according to the invention;

FIG. 2 is a schematic representation of a simulation arrangement for an array of tweeters of another embodiment of the loudspeaker system according to the invention;

FIG. 3 shows polar diagrams relating to simulations carried out with the measurement arrangement of FIG. 2 concerning the array as depicted in FIG. 2;

FIG. 4 shows a magnitude—angle—frequency graph corresponding to the polar diagrams depicted in FIG. 3; and

FIG. 5 is a schematic representation of an embodiment of an apparatus according to the invention.

### DETAILED DESCRIPTION OF EMBODIMENTS

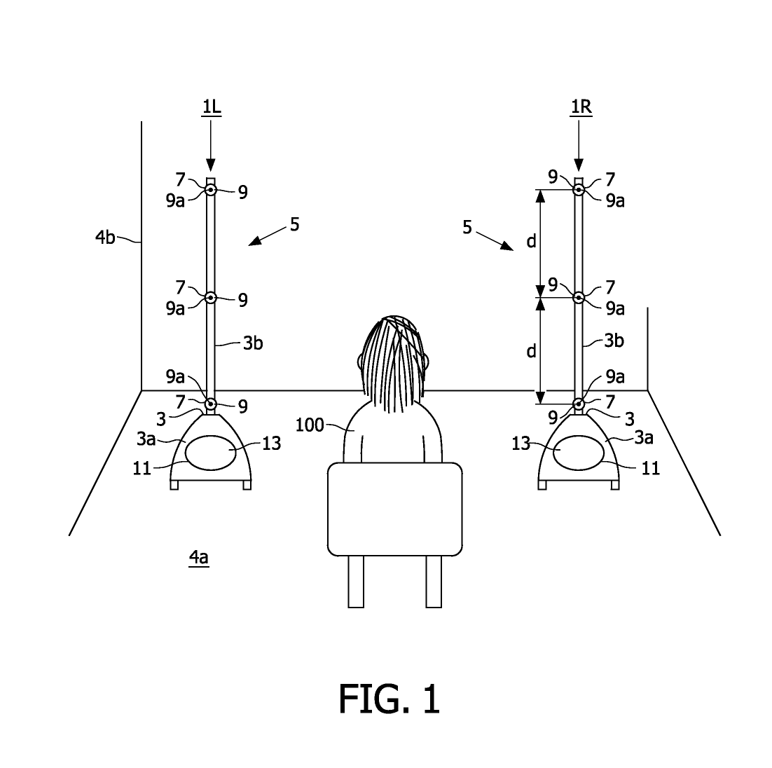

With reference to FIG. 1, there can be seen an arrangement of two stand-alone loudspeaker devices 1L and 1R positioned on the left hand and the right hand, respectively, and in front of an imaginary listener 100, present in a room having a floor 4a and a wall or walls 4b. Such loudspeaker device 1L, 1R has a frame 3, which comprises a box 3a and a stem 3b of e.g. a rod-like shape. A low end of the stem 3b is secured to the box 3a. The boxes 3a are meant for resting upon a face, such as the floor 4a, or the like. In this example each stem 3 is provided with three tweeters (first loudspeakers) 7 for reproducing sound in a high-frequency range, each tweeter 7 having a first radiation surface 9. In this example, each box 3a is provided with a woofer (second loudspeaker) 11 for reproducing sound on a low-frequency range, each woofer 11 having a second radiation surface 13. The woofers 11 may be woofers known per se. The tweeters 7 may be conventionally available tweeters having e.g. dome-shaped membranes, however preferably with the additional condition that the diameter of the limit radiation surfaces 9 is maximal 50 mm. In this example the crossover frequency f_{c} of the speaker arrangement is 1.5 kHz. The frequency range of the tweeters 7 is 900 Hz to 30 kHz and the frequency range of the woofers 11 is 60 Hz to 5 kHz. The tweeters 7 of each device 1L, 1R constitute an array 5 of tweeters 7, which arrays 5 are substantially vertically oriented. Each array 5 fulfills the essential condition λ_{f}_{_{c}}<d<1 m, wherein d is the distance between a central area 9a of each of the tweeters 7 and a central area 9a of a neighboring tweeter 7 and wherein λ_{f}_{_{c}} is the wave length of the reproduced sound at the crossover-frequency. In this example the distance d is 400 mm. The mentioned condition provides the design rule for spacing the tweeters 7 in each array 5.

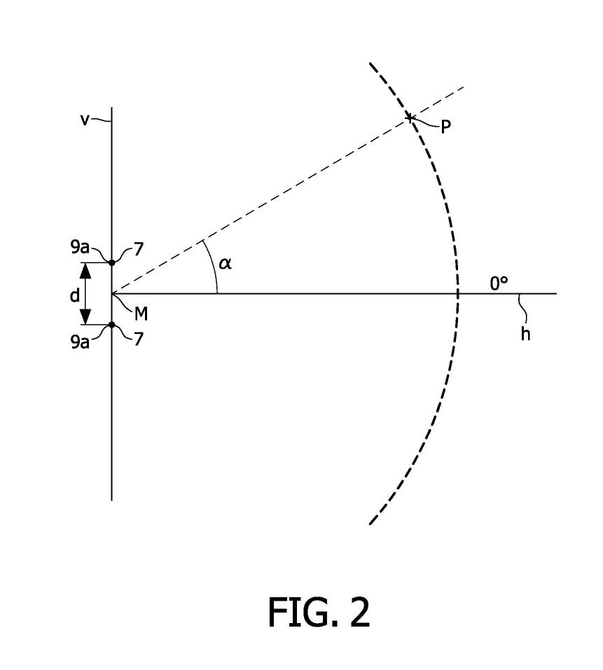

It is to be noted that in principle the same reference signs will be used in the following description relating to the embodiment of FIG. 2, for parts corresponding to similar parts in the embodiment of FIG. 2.

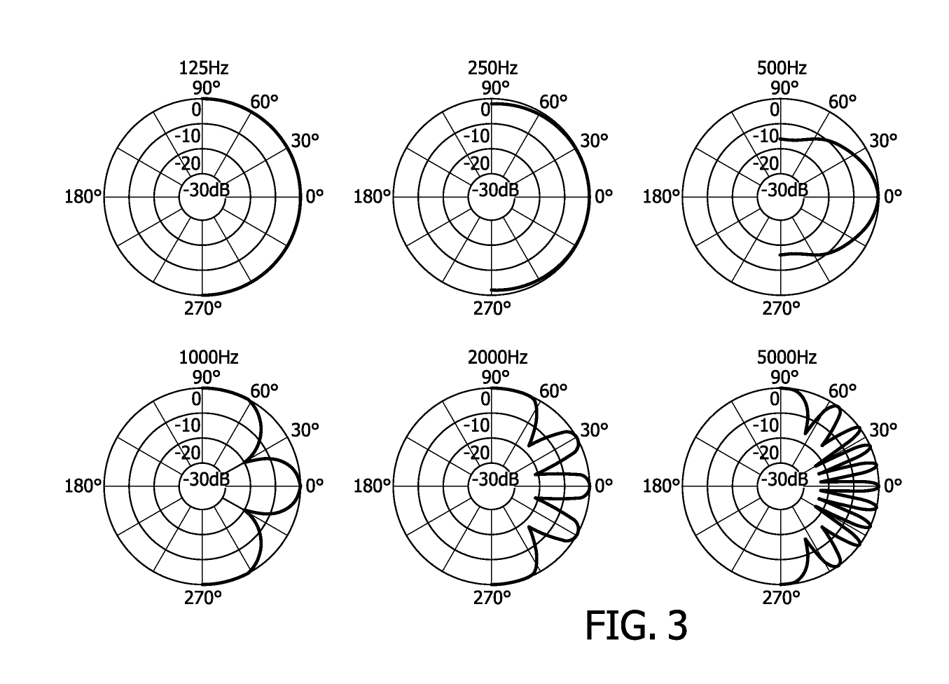

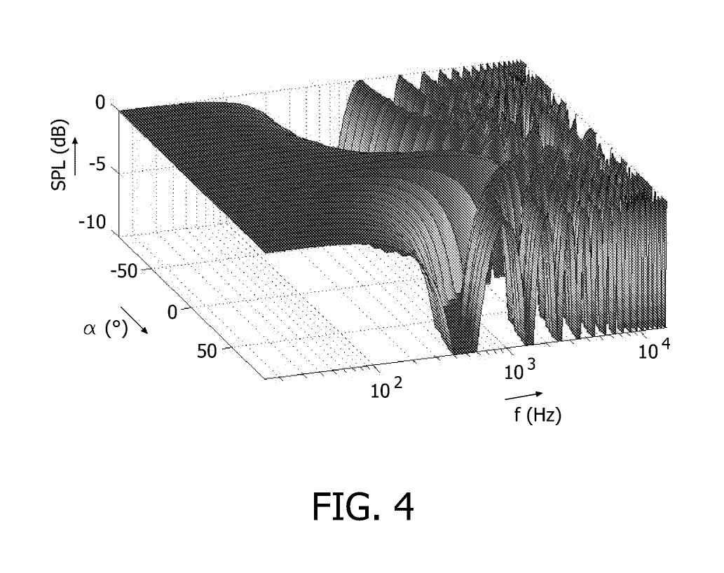

In FIG. 2 a simulation arrangement is shown for determining the sound output of an array, being an array in accordance with the rules of the invention. The array includes two tweeters 7, positioned one above the other at a distance d of 340 mm and meeting the requirement d>λ_{f}_{_{c}}. The following numerals in FIG. 2 are relevant: v being a vertical axis through the tweeters 7; h being a horizontal symmetry axis; P being a virtual microphone position at a distance of 2 m from the intersection M of the axes v and h; and a being the angle between the line P-M and the horizontal axis h. Furthermore it is noted that the simulation was done under anechoic conditions, wherein the tweeters 7 were considered in the simulation to be omni directional monopoles. The results of the simulation are depicted in the FIGS. 3 and 4.

FIG. 3 discloses polar diagrams showing the sound pressure levels (in dB) for several frequencies.

FIG. 4 discloses a graph showing the magnitude of the sound, i.e. the sound pressure level (SPL) as a function of the frequency (f) of the sound signals at various angles (α). These graphs clearly show that the tweeter configuration of FIG. 2 yields a substantially homogeneous spreading of energy lobes above the crossover frequency of 1 kHz. Under reverberant conditions, as occur in e.g. a living room, said energy lobes will provide an even more regular picture due to reflections.

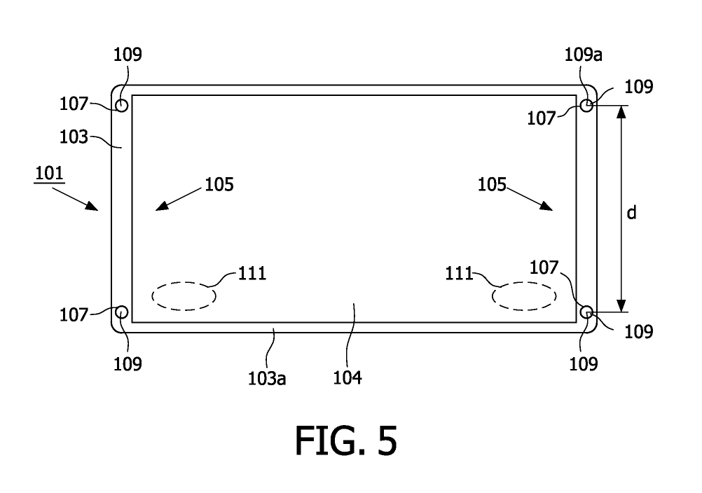

With reference now to FIG. 5 there can be seen an embodiment of the loudspeaker housing 101 according to the invention. In this example the loudspeaker housing 101 is constituted by a television housing 103 of a TV set having in its front face 103a a screen 104. In this example the loudspeaker housing 101 comprises two arrays 105 of two tweeters 107 each, which tweeters 107 have radiation surfaces 109 which are positioned in or near the front face 103a of the television housing 103, so that they are able to radiate sound from the front face 103a. The housing 101 is provided with one or more woofers 111, preferably mounted such that their radiation surfaces are positioned in or near a rear or side face of the television housing 103, so that they radiate sound during use from that face. The arrays 105 as applied in the loudspeaker housing 101 fulfills the following additional requirements: (1) the crossover frequency f_{c} is lying in the range from 750 Hz to 3000 Hz, and (2) the tweeters 107 of each array 105 are positioned at a vertical distance from each other measured from central area 109a to central area 109a, which distance d meets the requirement λ_{f}_{_{c}}<d<1 m. Preferably, the tweeters 107 are dome-shaped tweeters having a diameter of at most 50 mm.

It is to be noted that the invention is not limited to the embodiments disclosed herein. For example a subwoofer may be additionally applied for reproducing only bass frequencies. The frequency range of such a subwoofer may be from the resonance frequency of the subwoofer to about 200 Hz.

1. A loudspeaker system including
at least two stand-alone loudspeaker devices, each comprising a frame provided with an array, being a vertically oriented array, considering during use of the system, of first loudspeakers for reproducing sound in a higher frequency range, and
a second loudspeaker for reproducing sound in a lower frequency range, wherein the frequency ranges have a crossover frequency fc and 750 Hz≦fc≦3000 Hz, which first loudspeakers each have a first radiation surface, in each array a central area of each first radiation surface being situated at a distance d from the central are of a neighboring first radiation surface,
wherein. λ_{f}_{_{c}}<d<1 m, wherein λ_{f}_{_{c}} is the wavelength of the reproduced sound at the crossover frequency.

2. A loudspeaker system as claimed in claim 1, wherein the number of first loudspeakers in each array is at least 3.

3. A loudspeaker system as claimed in claim 1, wherein the first radiation surfaces in each array each have a dimension D, considered in the plane of the first radiation surface and perpendicular to the relevant array, wherein D<50 mm.

4. A loudspeaker system as claimed in claim 1, wherein 1000 Hz≦fc≦2000 Hz.

5. A system as claimed in claim 1, wherein the lower frequency range extends from a resonance frequency up to the crossover frequency.

6. A system as claimed in claim 1, wherein the higher frequency range extends from the crossover frequency.

7. A system as claimed in claim 1, wherein the first radiation surfaces each have a circular outline.

8. A system as claimed in claim 1, wherein the second loudspeaker is situated in a level underneath the arrays of first loudspeakers.

9. A system as claimed in claim 1, wherein the frame of each of the loudspeaker devices is provided with a second loudspeaker for reproducing sound in a lower frequency range.

10. A system as claimed in claim 1, wherein each first radiation surface is part of a dome-shaped membrane.

11. A loudspeaker housing accommodating at least one array, being a vertically oriented array, considered during use of the system, of first loudspeakers for reproducing sound in a higher frequency range, and at least one second loudspeaker for reproducing sound in a lower frequency range, the frequency ranges defining a crossover frequency fc, wherein 750 Hz≦fc≦3000 Hz, which first loudspeakers each have a first radiation surface, in each array a central array of each first radiation surface being situated at a distance d from the central area of a neighboring first radiation surface, wherein λ_{f}_{_{c}}<d<1 m, wherein λ_{f}_{_{c}} is the wavelength of the reproduced sound at the crossover frequency.

12. A loudspeaker housing as claimed in claim 11, wherein the first radiation surfaces each have a dimension D, considered in the first radiation surface and perpendicular to the array, wherein D<50 mm.

13. A housing as claimed in claim 11, wherein 1000 Hz<fc<2000 Hz.

14. A housing as claimed in claim 11, wherein the lower frequency range extends from a resonance frequency up to the crossover frequency.

15. A housing as claimed in claim 11, wherein the higher frequency range extends from the crossover frequency.

16. A housing as claimed in claim 11, wherein each first radiation surface has a circular outline and a diameter of 50 mm at the most.

17. A housing as claimed in claim 11, wherein the second loudspeaker is mounted in a rear wall of the housing.

18. A housing as claimed in claim 11, wherein the first radiation surface is part of a dome-shaped membrane.

19. A housing as claimed in claim 11, wherein a further similar array of first loudspeakers is accommodated.

20. An audio and/or video apparatus provided with a loudspeaker arrangement formed by the system as claimed in claim 1.

21. A stand-alone loudspeaker device, suitable for use in the loudspeaker system as claimed in claim 1, comprising a frame provided with an array of first loudspeakers for reproducing sound in a higher frequency range, which first loudspeakers each have a first radiation surface, in each array a central area of each first radiation surface being situated at a distance d from the central area of a neighboring first radiation surface, wherein λ_{f}_{_{c}}<d<1 m, wherein λ_{f}_{_{c}} is the wavelength of the reproduced sound at a frequency between substantially 750 Hz and 3000 Hz.
